(19) United States
(12) Patent Application Publication
(10) Pub. No.: US 2011/0083606 A1
(43) Pub. Date: Apr. 14, 2011

(54) EXHAUST GAS TREATMENT DEVICE FOR A CVD DEVICE, CVD DEVICE, AND EXHAUST GAS TREATMENT METHOD

(76) Inventors: Joachim Rudhard, Leinfelden-Echterdingen (DE); Thorsten Mueller, Reultingen (DE)

(21) Appl. No.: 12/922,820

(22) PCT Filed: Jan. 23, 2009
(86) PCT No.: PCT/EP09/50793

§ 371 Date: Dec. 8, 2010

(30) Foreign Application Priority Data
Mar. 17, 2008 (DE) 10 2008 014 654.4

(51) Int. Cl. C23C 16/56; B01D 46/46

(52) U.S. Cl. 118/715; 96/422; 95/23; 95/12

(57) ABSTRACT

An exhaust gas treatment device for a CVD device for the deposition of silicon-rich nitride in a CVD process, in particular an LPCVD process. An aftertreatment chamber is provided into which ammonia gas can be metered. In addition, a CVD device and an exhaust gas treatment method are described.

### FIELD OF THE INVENTION

The present invention relates to an exhaust gas treatment device for a CVD device (Chemical Vapor Deposition device), a CVD device, and a method for treating exhaust gas from a CVD process.

### BACKGROUND INFORMATION

Conventionally, for the deposition of thin layers, a so-called CVD process (Chemical Vapor Deposition process) is used. In this process, a solid component is deposited from a gas phase on the surface of a substrate in a CVD process chamber on the basis of a chemical reaction. The deposition of layers using a conventional LPCVD (Low Pressure Chemical Vapor Deposition) process, in which the layer is deposited at a low process pressure, is also used. In particular in semiconductor technology and MEMS (Micro-Electro-Mechanical-System) technology, silicon nitride is deposited using an LPCVD process. For this purpose, DCS (dichlorosilane) and NH₃ (ammonia gas) are deposited in a stoichiometric equilibrium. The reaction chemistry of this process is as follows:

3 SiH₂Cl₂+NH₃→Si₃N₄+NH₄Cl+5 HCl+6H₂.

The cleaning of exhaust gas for an LPCVD process for depositing stoichiometric silicon nitride is controlled by an exhaust gas pipe heated up to a cooling trap, with an acceptable expense.

A disadvantage of the stoichiometric nitride layer is that this layer stands under a high tensile stress of approximately 1 GPa, and therefore for example cannot be deposited in an arbitrary thickness. This and other reasons led to the development of silicon-rich nitride layers that can be deposited on the same supports by processing with an excess of DCS. The advantage of these silicon-rich nitride layers is that the layer stress of these layers can be set over a large range of tensile stress, even up to a slight pressure stress. A disadvantage of the processing with an excess of DCS is that the resulting reaction products contained in the exhaust gas are deposited in the exhaust gas line on pipes, valves, and in the cooling trap, which causes failure of components in the exhaust gas line in a very short time.

European Patent No. EP 0 839 929 B1 describes an exhaust gas cleaning device for a CVD process. Here, microwaves are used to produce a plasma in the exhaust gas line.

### SUMMARY

An object of the present invention is to provide an exhaust gas treatment device for a CVD device for depositing silicon-rich nitride that ensures a long durability of components of the exhaust gas line. In addition, an object of the present invention is to provide a correspondingly optimized CVD device, as well as a method for treating exhaust gas from a CVD process in which silicon-rich nitride is deposited.

Advantageous developments of the present invention are described below. All combinations of at least two of the features described and/or in the figures fall within the scope of the present invention.

According to an example embodiment of the present invention, an aftertreatment chamber for exhaust gas treatment is provided. The chamber is situated after the actual CVD process, in particular the LPCVD process, it being possible to meter ammonia gas (NH₃) into the aftertreatment chamber. The addition of ammonia gas to the exhaust gas of the CVD process forces the deposition of silicon nitride in the aftertreatment chamber, and the reaction of dichlorosilane (DCS) and ammonia gas results in the standard reaction by-products, which can be controlled using conventional exhaust gas treatment methods. In order to enable the deposition of larger quantities of silicon nitride, in particular stoichiometric silicon nitride, it is advantageous to provide a large reaction surface in the aftertreatment chamber. The aftertreatment chamber can thus be constructed in a manner similar to the actual process chamber of the DVD process. It is also possible to provide, as an aftertreatment chamber, an exhaust gas line into which ammonia gas can be introduced. By adding ammonia gas to the exhaust gas from the CVD process, the reaction products that result when silicon-rich nitride is deposited in the actual CVD process chamber can be at least minimized, relieving the burden on the exhaust gas line that is situated after the aftertreatment chamber and that includes at least one cooling trap.

In order to enable the exhaust gas treatment process to be monitored or controlled in a targeted manner, a specific embodiment is preferred in which the quantity of ammonia gas that is to be added to the exhaust gas can be adjusted in such a way that stoichiometric nitride is deposited. In other words, at least approximately enough ammonia gas is subsequently added that there results in the exhaust gas, in particular in the aftertreatment chamber, a stoichiometric equilibrium between DCS and NH₃, so that, at least generally, only exhaust gas exits the aftertreatment chamber, corresponding in its composition at least approximately to the exhaust gas of a stoichiometric CVD deposition process for the deposition of stoichiometric nitride. If warranted, the quantity of ammonia gas to be added to the exhaust gas can also be selected such that there results an excess of ammonia gas in the aftertreatment chamber. An excess of ammonia gas in the exhaust gas exiting the aftertreatment chamber can be controlled relatively easily in terms of the process used.

In a particularly advantageous specific embodiment of the exhaust gas treatment device, this device is fashioned such that the amount of ammonia gas to be added to the exhaust gas is determined as a function of the CVD process flow ratio of dichlorosilane to ammonia gas. In other words, the exhaust gas treatment device includes an arrangement for determining the process flow ratio of dichlorosilane to ammonia gas, the process flow ratio of the two substances being taken into account in the determination of the quantity of ammonia gas that is subsequently to be metered. Additionally or alternatively, the quantity of ammonia to be subsequently metered can be determined as a function of the quantity of ammonia gas (concentration) and/or the quantity of dichlorosilane (concentration) in the exhaust gas of the CVD process. In other words, according to this specific embodiment, the exhaust gas treatment device includes an arrangement for determining the quantity of ammonia gas and/or the quantity of dichlorosilane in the exhaust gas, in particular in order to detect the quantity of ammonia gas and/or the quantity of dichlorosilane in the aftertreatment chamber. In particular if the aftertreatment chamber is elongated, i.e., the aftertreatment chamber is fashioned in the manner of an exhaust gas pipe, it is possible to add ammonia gas at at least two locations of the aftertreatment chamber that are situated at a distance from one another in the direction of flow of the exhaust gas, in particular as a function of the concentration of dichlorosilane and/or the concentration of ammonia gas in the area of the respective location at which the gas is to be added.

Particularly preferred is a specific embodiment of the exhaust gas treatment device in which this device has a logic unit for determining and regulating the quantity of ammonia gas that is to be added. Here, a specific embodiment can be realized in which a table is stored in the logic unit, or in a storage device of the logic unit, from which the quantity of ammonia gas to be added to the exhaust gas can be determined as a function of at least one value that is to be determined. In addition or alternatively to a table, a corresponding calculation algorithm may also be stored. If, for example, the CVD process flow ratio of dichlorosilane to ammonia gas is known, the logic unit can determine the quantity of ammonia gas that is to be added to the exhaust gas on the basis of the table and/or using the algorithm. Alternatively, the quantity of ammonia gas to be added can be determined for example on the basis of the quantity of dichlorosilane (concentration) that is to be measured in the exhaust gas, based on the table and/or using the algorithm. The logic unit can be a component of a metering ammonia gas flow quantity controller that can be provided for the later addition of ammonia gas to the aftertreatment chamber.

In order to supply the logic unit with current data, in particular measurement data, a specific embodiment is preferred in which the logic unit is connected in signal-conducting fashion to at least one CVD process dichlorosilane flow quantity meter and/or at least one CVD process ammonia gas flow quantity meter in order to determine the CVD process flow ratio. In addition or alternatively, the logic unit can also be connected to a dichlorosilane flow quantity controller (mass flow controller) and/or to an ammonia gas flow quantity controller (mass flow controller) that forward(s) the current flow quantity or quantities to the logic unit. In a development of the present invention, it is advantageously provided that the logic unit is a component of a metering ammonia gas flow quantity controller (mass flow controller).

Particularly advantageous is a specific embodiment in which the logic unit is connected in signal-conducting fashion to an ammonia sensor for determining the quantity of ammonia, in particular the concentration of ammonia, in the exhaust gas of the CVD process, in particular in the aftertreatment chamber, and/or to a dichlorosilane sensor for determining the quantity of dichlorosilane, in particular the concentration of dichlorosilane, in the exhaust gas, preferably in the aftertreatment chamber. Here the determination of the quantity of ammonia gas that is to be subsequently metered can be determined as needed exclusively on the basis of this sensor data. However, a specific embodiment is particularly preferred in which this sensor information is determined in addition to the CVD process flow ratio, in order to enable the amount of ammonia gas that is actually required to be determined as precisely as possible.

In a development of the present invention, it is advantageously provided that the aftertreatment chamber is fashioned in the manner of a CVD process chamber. In other words, in addition to a large reaction surface a heating system is preferably provided for the heating of the aftertreatment chamber, in particular at least approximately to the CVD process temperature, in order to promote a deposition of stoichiometric nitride. For the case in which an exhaust gas line is also connected after the aftertreatment chamber and leads to a cooling trap for the deposition of ammonium chloride, a specific embodiment is preferred in which this exhaust gas line can likewise be heated preferably approximately to the CVD process temperature, preferably over its entire length but at least in some segments, in order also to enable a deposition of stoichiometric nitride in the exhaust gas line.

In addition to the exhaust gas treatment device, the present invention also results in a CVD device having an exhaust gas treatment device as described above, the exhaust gas treatment device being situated after a CVD process chamber in the direction of flow.

In addition, the present invention results in a method for treating exhaust gas from a CVD process, in particular from an LPCVD process, in which silicon-rich nitride is deposited, in particular on a substrate. According to the present invention, it is provided that ammonia gas is added to the exhaust gas from the CVD process, preferably in such a way that stoichiometric nitride is deposited from the exhaust gas. The addition of ammonia gas to the exhaust gas from the CVD process at least reduces an excess of dichlorosilane in the exhaust gas, as well as aggressive reaction products resulting therefrom, and preferably completely balances them, with the advantage that standard reaction products are obtained, in particular NH₄Cl, HCl, and H₂, as in the case of stoichiometric CVD process control.

In a development of the present invention, it is advantageously provided that the quantity of ammonia gas that can be added to the exhaust gas is adjusted in such a way that stoichiometric nitride is deposited from the exhaust gas and/or that an excess of ammonia gas—preferably only a slight excess—results in the exhaust gas.

In a development of the present invention, it is advantageously provided that the quantity of ammonia gas that can be added to the exhaust gas is determined as a function of the CVD process flow ratio of dichlorosilane to ammonia gas; for this purpose, the volume flow of dichlorosilane supplied to the CVD process and the volume flow of ammonia gas supplied to the CVD process are preferably determined or calculated. Alternatively or in addition, the quantity of ammonia that can be added to the exhaust gas can be set as a function of the quantity of ammonia gas (ammonia gas concentration) or the quantity of dichlorosilane (dichlorosilane concentration) in the exhaust gas of the CVD process, in particular in an aftertreatment chamber. For this purpose, the ammonia gas concentration and/or the dichlorosilane concentration in the exhaust gas are to be determined using suitable sensors.

Particularly advantageous is a specific embodiment in which, in order to accelerate the reaction, the exhaust gas and/or the ammonia gas that can be added to the exhaust gas are heated, preferably to the CVD process temperature.

### BRIEF DESCRIPTION OF THE DRAWINGS

Further advantages, features, and details of the present invention are described below with reference to preferred exemplary embodiments, and on the basis of the figures.

FIG. 1 shows a CVD device having an exhaust gas treatment device connected after a CVD process chamber.

FIG. 2 shows an alternative CVD device.

### DETAILED DESCRIPTION OF EXAMPLE EMBODIMENTS

In the figures, identical components and components having identical functions have been identified with the same reference characters.

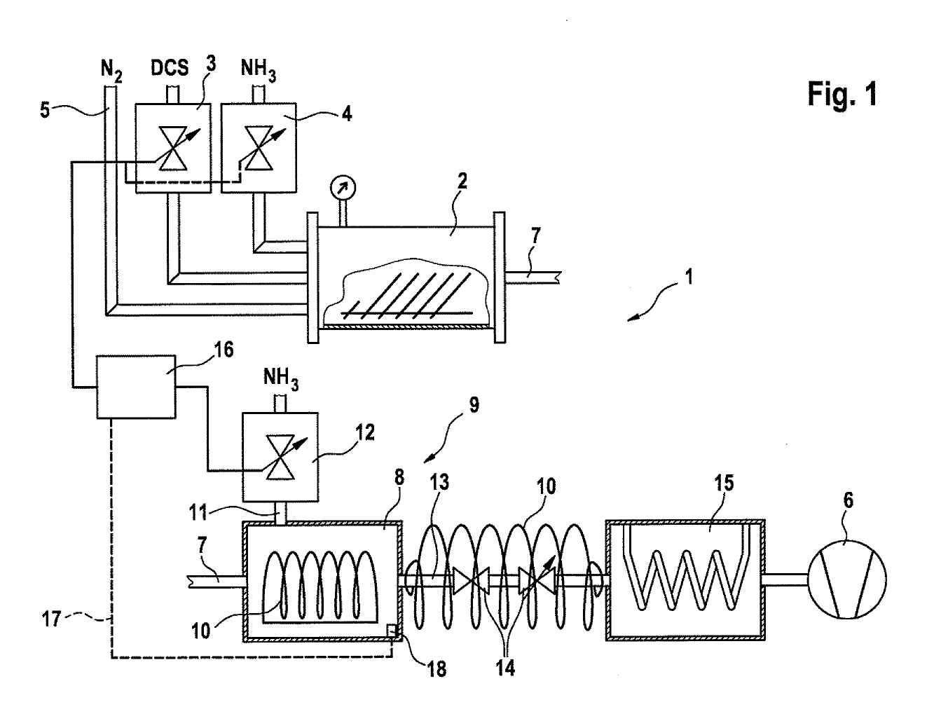

FIG. 1 shows a CVD device 1 for carrying out an LPCVD process for the deposition of silicon-rich nitride. The CVD

FIG. 1 shows a CVD device 1 for carrying out an LPCVD process for the deposition of silicon-rich nitride. The CVD device includes a CVD process chamber 2 that is fashioned in a known manner. The CVD process chamber has in its interior one or more substrates, up to typically used batch process sizes, having a large reaction surface, and is capable of being heated (not shown).

CVD process chamber 2 has allocated to it a dichlorosilane flow quantity controller 3 (mass flow controller) via which the dichlorosilane (DCS) process flow can be adjusted. In addition, CVD process chamber 2 has allocated to it an ammonia gas flow quantity controller 4 (mass flow controller) via which the ammonia gas (NH₃) process flow can be controlled. In addition, a nitrogen (N₂) line 5 leads into CVD process chamber 2, in particular for the purpose of rinsing.

In the depicted CVD device 1, an excess quantity of dichlorosilane is introduced into CVD process chamber 2, so that, under a partial vacuum created by a pump 6, silicon-rich nitride is deposited onto the substrate or substrates in CVD process chamber 2.

An exhaust gas pipe 7 leads out from CVD process chamber 2 and leads to an aftertreatment chamber 8 of an exhaust gas treatment device 9. Aftertreatment chamber 8 is equipped with a heating device 10 for heating the interior of aftertreatment chamber 8 to the CVD process temperature.

Ammonia gas can be metered into aftertreatment chamber 8. For this purpose, a metering line 11 opens into aftertreatment chamber 8 (alternatively, metering line 11 opens into exhaust gas pipe 7). Metering line 11 connects a metering ammonia gas flow quantity controller 12 (mass flow controller) to aftertreatment chamber 8. From aftertreatment chamber 8 there runs an exhaust gas line 13 that leads, via valves 14, to a cooling trap 15 in which ammonium chloride is deposited. The exhaust gas line that follows aftertreatment chamber 8 corresponds to a conventional exhaust gas line for a stoichiometric nitride deposition process. Pump 6 for conveying the exhaust gas and for creating a partial vacuum in CVD process chamber 2 and in aftertreatment chamber 8 is situated after cooling trap 15.

Metering ammonia gas flow quantity controller 12 is controlled via a logic unit 16 that is connected in signal-conducting fashion both to a dichlorosilane flow quantity controller 3 and to ammonia gas flow quantity controller 4. Logic unit 16 determines the quantity of ammonia gas that is to be metered into aftertreatment chamber 8 as a function of the CVD process flow ratio of dichlorosilane to ammonia gas. In the exemplary embodiment shown, the quantity of ammonia gas to be metered is determined by logic unit 16 on the basis of a table in such a way that in the exhaust gas in aftertreatment chamber 8 there arises at least approximately a stoichiometric ratio of dichlorosilane and ammonia gas, so that the dichlorosilane excess remaining from the CVD process is reduced, by the deposition of nitride in aftertreatment chamber 8, to the standard reaction products (NH₄Cl, HCl, H₂) of a stoichiometric process controlling. In order to maintain the exhaust gas reaction process up to cooling trap 15, exhaust gas line 13 can also be heatable by a heating device 10.

Dashed lines indicate a signal line 17 that may optionally also be provided. Signal line 17 connects an ammonia gas sensor 18 (also optional) to logic unit 16, so that ammonia gas can be subsequently controlled as needed if ammonia gas sensor 18 determines that the level of ammonia gas is too low.

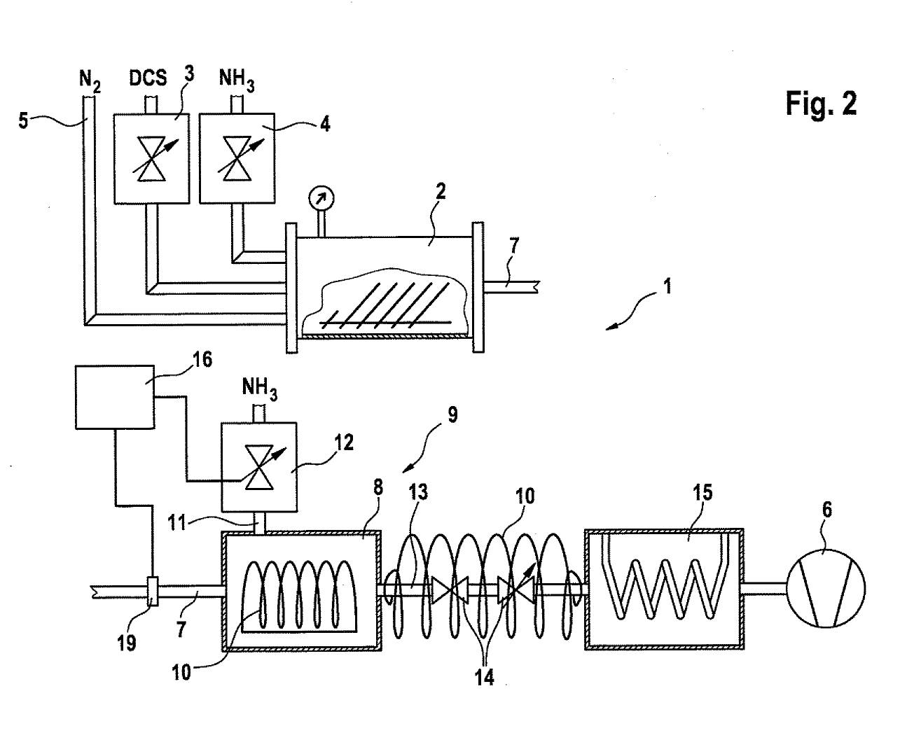

FIG. 2 shows an alternative exemplary embodiment of a CVD device 1 having an exhaust gas treatment device 9. Here, CVD device 1 corresponds generally to the exemplary embodiment according to FIG. 1, so that, in order to avoid repetition, in the following only the differences from the exemplary embodiment according to FIG. 1 are discussed. With regard to features in common, reference is made to the preceding description of the Figure and to FIG. 1.

In contrast to the exemplary embodiment according to FIG. 1, the determination of the quantity of ammonia gas that is to be metered into aftertreatment chamber 8 takes place as a function of the concentration of dichlorosilane in the exhaust gas. For this purpose, in exhaust gas pipe 8 there is integrated a dichlorosilane sensor 19 that is connected in signal-conducting fashion to logic unit 16, which in turn controls metering ammonia gas flow quantity controller 12. Alternatively or in addition to a dichlorosilane sensor 19 in exhaust gas pipe 7, there may also be provided in exhaust gas pipe 7 an ammonia gas sensor 18 for determining the ammonia gas concentration in the exhaust gas. The corresponding sensors may also be provided in aftertreatment chamber 8 as needed. Thus, differing from the exemplary embodiment shown in FIG. 1, the quantity of ammonia gas that is to be added to the exhaust gas is not determined immediately from the CVD process flow ratio of dichlorosilane to ammonia gas, but rather on the basis of a direct measurement of the quantity of dichlorosilane and/or the quantity of ammonia gas in the exhaust gas.

1-13. (canceled)

14. An exhaust gas treatment device for a CVD device for the deposition of silicon-rich nitride in a CVD process, comprising:
an aftertreatment chamber into which ammonia gas can be metered.

15. The exhaust gas treatment device as recited in claim 14, wherein a quantity of ammonia gas that is to be metered is adjustable in such a way that at least one of stoichiometric nitride is deposited, and an excess of ammonia gas results in the aftertreatment chamber.

16. The exhaust gas treatment device as recited in claim 14, wherein a quantity of ammonia that can be metered can be adjusted as a function of at least one of a flow ratio of the CVD process of dichlorosilane to ammonia gas, a quantity of ammonia gas, and a quantity of dichlorosilane in exhaust gas in the aftertreatment chamber.

17. The exhaust gas treatment device as recited in claim 16, further comprising:
a logic unit for continuous determination of the quantity of ammonia gas that is to be metered.

18. The exhaust gas treatment device as recited in claim 17, wherein the logic unit is connected in signal-conducting fashion to at least one of: i) at least one dichlorosilane flow quantity meter, ii) at least one dichlorosilane flow quantity controller, iii) an ammonia gas flow quantity meter, and iv) an ammonia gas flow quantity controller.

19. The exhaust gas treatment device as recited in claim 17, wherein the logic unit is a component of a metering ammonia gas flow quantity controller adapted to meter the ammonia gas into the aftertreatment chamber.

20. The exhaust gas treatment device as recited in claim 17, wherein the logic unit is connected in signal-conducting fashion to at least one of an ammonia gas sensor that determines the quantity of ammonia in the exhaust gas of the CVD process in the aftertreatment chamber and a dichlorosilane sensor that determines a quantity of dichlorosilane in the exhaust gas in the aftertreatment chamber.

21. The exhaust gas treatment device as recited in claim 17, further comprising:
at least one heating device to at least one of heat the aftertreatment chamber and to heat an exhaust gas line leading to a cooling trap for deposition of ammonium chloride at least approximately to a temperature of the CVD process.

22. A CVD device, comprising:
a CVD process chamber; and
an exhaust gas treatment device including an aftertreatment chamber into which ammonia gas can be metered.

23. A method for treating exhaust gas from a CVD process, in which silicon-rich nitride is deposited, comprising:
metering ammonia gas to the exhaust gas from the CVD process.

24. The method as recited in claim 23, further comprising:
adjusting a quantity of ammonia gas that can be metered to the exhaust gas in such a way that at least one stoichiometric nitride is deposited, and an excess of ammonia gas results in the exhaust gas.

25. The method as recited in claim 23, further comprising:
adjusting a quantity of ammonia that can be metered to the exhaust gas as a function of at least one of a flow ratio of dichlorosilane to ammonia gas, a quantity of ammonia gas, and a quantity of dichlorosilane in the exhaust gas of the CVD process in an aftertreatment chamber.

26. The method as recited in claim 23, further comprising:
heating at least approximately to a temperature of the CVD process at least one of the exhaust gas and the ammonia gas that can be metered to the exhaust gas.
